(19) United States
(12) Patent Application Publication
(10) Pub. No.: US 2008/0238461 A1
(43) Pub. Date: Oct. 2, 2008

(54) Multi-type test interface system and method

(76) Inventors: Ken Skala, Fremont, CA (US); Jeff Currin, Livermore, CA (US); Curtis Hainds, Colorado Springs, CO (US); Carlos Ramos, San Jose, CA (US)

Correspondence Address: MURABITO HAO & BARNES LLP, Third floor, Two North Market Street, San Jose, CA, 95113, US

(21) Appl. No.: 11/827,274

(22) Filed: Jul. 10, 2007

Related U.S. Application Data
(60) Provisional application No. 60/921,634, filed on Apr. 2, 2007.

(51) Int. Cl. G01R 31/02

(52) U.S. Cl. 324/758

(57) ABSTRACT

Efficient automated testing systems and methods are presented. In one embodiment, an automated testing system includes a plurality of bucket modules, and a device under test transition interface. The plurality of bucket modules have similar external connection form factors for a variety of instruments. The interface is for transitioning connections from the plurality of bucket modules to a device under test.

### RELATED APPLICATIONS

This application claims the benefit and priority of Provisional Patent Application 60/921,634 entitled “A MULTI-TYPE TEST INTERFACESYSTEM AND METHOD” (Attorney Docket No. CRDC-P0782.PRO) filed Apr. 2, 2007, which is incorporate herein by this reference.

### FIELD OF THE INVENTION

The present invention relates to the field of automated test equipment.

### BACKGROUND OF THE INVENTION

Electronic and optical systems have made a significant contribution towards the advancement of modern society and are utilized in a number of applications to achieve advantageous results. Numerous electronic technologies such as digital computers, calculators, audio devices, video equipment, and telephone systems have facilitated increased productivity and reduced costs in analyzing and communicating data in most areas of business, science, education and entertainment. Electronic systems providing these advantageous results are often complex and are tested to ensure proper performance. However, traditional approaches to automated testing can be relatively time consuming and expensive.

A device under test (DUT) can often have a variety of different types of functions. Traditionally those different types of functions are tested separately in different insertions. Coordinating and executing multiple different insertions can take a significant amount of time and resources. In addition, different types of packages can introduce added complexity. Some system-in-package (SIP) and multi-chip packages (MCP) usually have multiple DUTs in the same package that perform tasks independently and often involve a user performing a variety of testing to test the different DUTs. The different functions can have fundamental significant differences. For example, radio frequency (RF) and non-radio frequency (non-RF) functions can have radically different testing characteristics that can impact the test production throughput.

### SUMMARY

Efficient automated testing systems and methods are presented. In one embodiment, an automated testing system includes a plurality of bucket modules, and a device under test transition interface. The plurality of bucket modules have similar external connection form factors for a variety of instruments. The interface is for transitioning connections from the plurality of bucket modules to a device under test.

### DESCRIPTION OF THE DRAWINGS

The accompanying drawings, which are incorporated in and form a part of this specification, illustrate embodiments of the invention by way of example and not by way of limitation. The drawings referred to in this specification should be understood as not being drawn to scale except if specifically noted.

FIG. 1 is a block diagram of an exemplary testing system in accordance with one embodiment of the present invention.

FIG. 2 is a block diagram of an exemplary interface in accordance with one embodiment of the present invention.

FIG. 3 is a block diagram of an exemplary interface from on top of an interface door in accordance with one embodiment of the present invention.

FIG. 4A shows an exemplary interface door with a plate on one side to cover a gap between brackets and the door in accordance with one embodiment of the present invention.

FIG. 4B shows an exemplary interface door with a plate on another side to cover a gap between brackets and the door in one accordance with one embodiment of the present invention.

FIG. 5A shows an exemplary bracket in an extended position sitting on an RF module in accordance with one embodiment of the present invention.

FIG. 5B shows an exemplary bracket in a compressed position sitting on an RF module in accordance with one embodiment of the present invention.

FIG. 5C is a block diagram of an exemplary portion of a load board in accordance with one embodiment of the present invention.

FIG. 5D is a block diagram of the bottom view of an exemplary bracket in accordance with one embodiment of the present invention.

FIG. 6 is diagram of a load board sitting on two RF OSP brackets in accordance with one embodiment of the present invention.

FIG. 7 is a flow chart of an exemplary test system interface method in accordance with one embodiment of the present invention.

### DETAILED DESCRIPTION

Reference will now be made in detail to the preferred embodiments of the invention, examples of which are illustrated in the accompanying drawings. While the invention will be described in conjunction with the preferred embodiments, it will be understood that they are not intended to limit the invention to these embodiments. On the contrary, the invention is intended to cover alternatives, modifications and equivalents, which may be included within the spirit and scope of the invention as defined by the appended claims. Furthermore, in the following detailed description of the present invention, numerous specific details are set forth in order to provide a thorough understanding of the present invention. However, it will be obvious to one of ordinary skill in the art that the present invention may be practiced without these specific details. In other instances, well known methods, procedures, components, and circuits have not been described in detail as not to unnecessarily obscure aspects of the present invention.

Present invention automated testing equipment systems and methods are described. In one embodiment, a variety of different types of testing are facilitated in single insertion of a device under test (DUT) on testing equipment. Testing configuration flexibility can facilitate testing via a variety of different type of connections. In one exemplary implementation, radio frequency (RF) and non-RF testing are performed in a single insertion. Different types of connections can be coordinated for single insertion in substantially the same plane. Automotive capabilities associated with the insertion activities can also be included. These and other features are set forth in more detail in the following description.

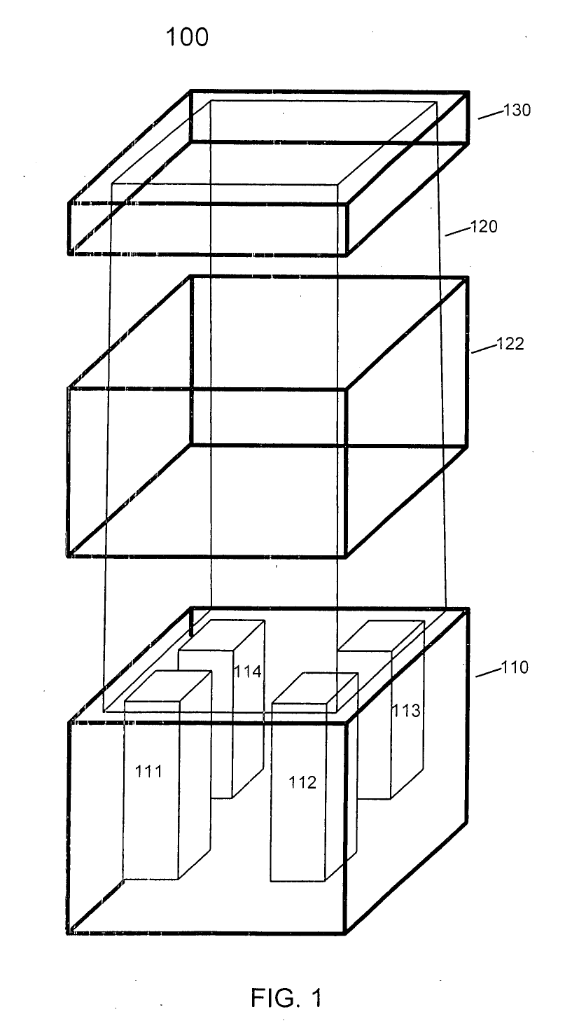

FIG. 1 is a block diagram of testing system 100 in accordance with one embodiment of the present invention. Testing system 100 includes a test head main component 110, an interface 120 and a device under test (DUT) board 130. In one embodiment, test head main component 110 includes a plurality of bucket modules 111, 112, 113, and 114. In one exemplary implementation, testing system includes an interface door body 122. It is appreciated that an interface mechanism of interface 120 can have a variety of configurations. In one exemplary implementation, the interface mechanism is coupled to the bucket modules and matches with openings in the interface door body 122.

The components of testing system 100 cooperatively operate to facilitate testing of a variety of devices under test. The main head component 110 is configured to receive a plurality of bucket modules. The plurality of bucket modules 111, 112, 113, and 114 include test instruments. In one embodiment, a bucket module can include a variety of different test instruments. For example, a bucket module can include instruments for performing radio frequency (RF) testing, non-RF testing, digital testing, linear testing, etc. DUT board 130 receives a device under test. Interface 120 transitions connections from the plurality of bucket modules to the DUT board body 130 for coupling with a device under test.

In one embodiment, the external connection form factor of the bucket modules to the test head component 110 body are similar. In one exemplary implementation, the plurality of bucket modules are interchangeable in different bucket module receptacles of the test head component 110 body. For example, a bucket module receptacle can receive an RF test bucket module and/or a digital test bucket module and/or a linear test bucket module and/or combinations thereof. In one embodiment, the support function features (e.g., power connections, cooling, etc.) are similar facilitating interchangeability of bucket modules. The size of the bucket modules and fastening or mounting mechanisms can also be similar to also facilitate interchangeability.

In one embodiment, the plurality of buckets can be directed to testing a variety of different types of functions. In one exemplary implementation, the plurality of buckets include a RF bucket for testing RF features of a device under test. The plurality of buckets can also include a non-RF bucket for testing non-RF features of a device under test. The plurality of buckets can include a digital bucket for testing digital features of a device under test and/or the plurality of buckets can include a linear bucket for testing linear features of a device under test.

Interface 120 can accommodate a variety of connection configurations and characteristics. In one embodiment, interface 120 facilitates coupling of a variety of different types of test signals from the plurality of buckets to a device under test. In one embodiment, interface 120 includes a transition mechanism for facilitating coupling in substantially a same plane. In one exemplary implementation, interface door 122 when opened permits access to the plurality of bucket modules.

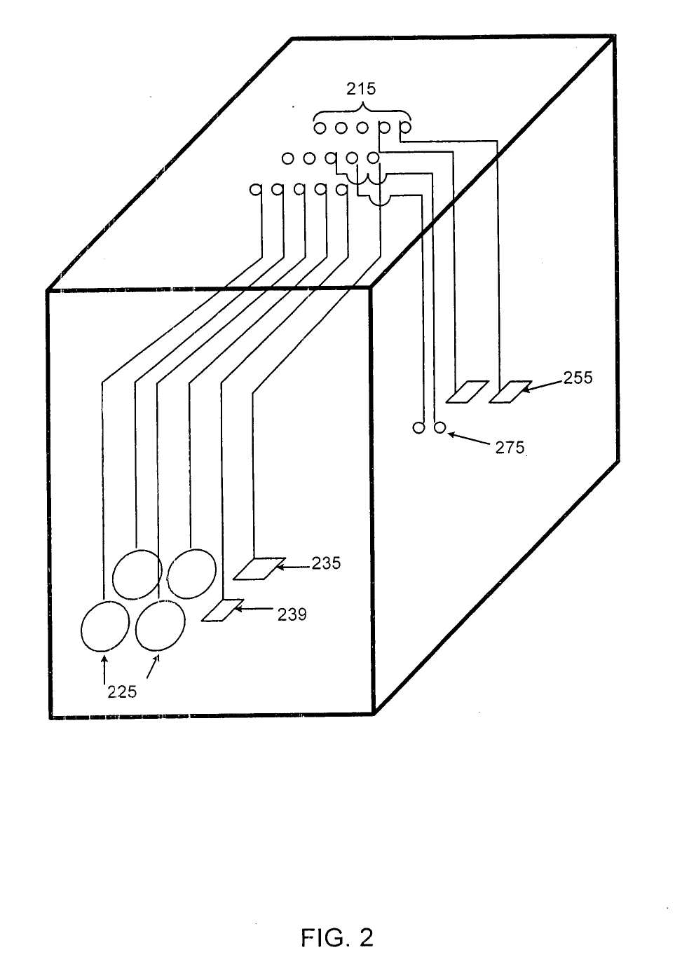

FIG. 2 is a block diagram of an exemplary interface 200 in accordance with one embodiment of the present invention. In one embodiment the interface facilitates coupling of a variety of different connectors. Interface 200 facilitates coupling of a first connector type 225, a second connector type 235, a third connector type 255 to a fourth connector type 215. The connectors can be configured so that the same type of connectors are included in the same bucket module or different types of connectors are included in the same bucket. For example, first connector type 225 can be RF connectors associated with a first bucket and connector 255 can be a digital type of connector associated with a second bucket. Different types of connectors can be included in a bucket module. For example, an RF connector 235 and a linear connector type 235 can be included in the same bucket module.

In one exemplary implementation, the interface also facilitates tighter configuration of connectors in a DUT board. For example, connectors 215 can be pogo or pin connectors that are in a much fighter configuration than the connectors 225, 255, etc.

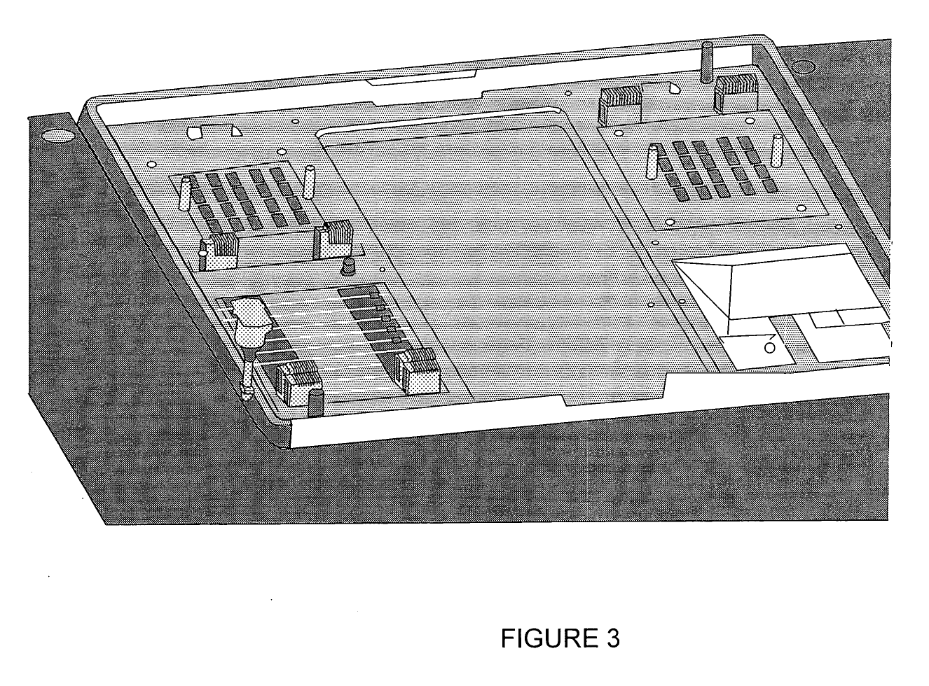

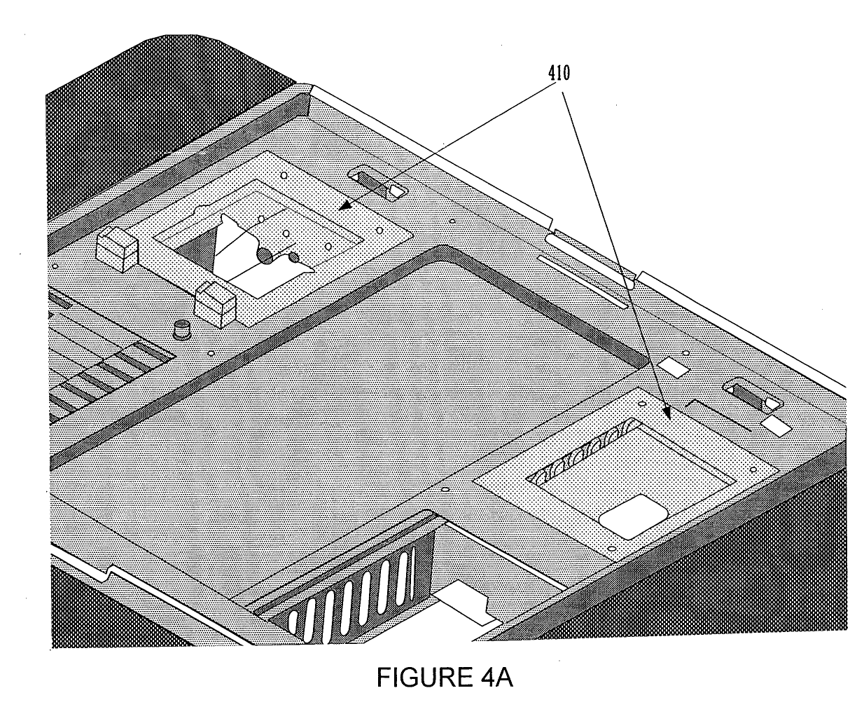

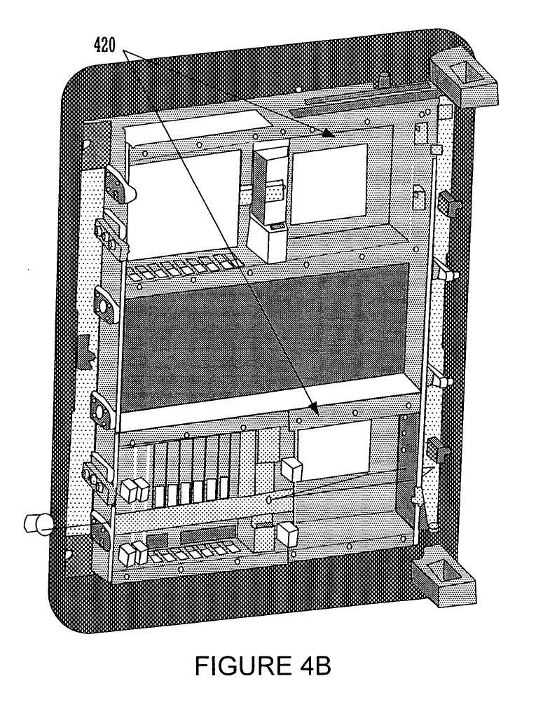

FIG. 3 is a block diagram of interface 300 in accordance with one embodiment of the present invention. FIG. 3 shows two RF modules with OSP brackets sitting in the interface door. FIGS. 4A and 4B show an exemplary interface door 300 with plates to cover a gap between the OSP brackets and the door. One plate shown typically as 410 is on one side (e.g., a “top” side) as shown in FIG. 4A and one plate shown typically as 420 is on another side (e.g., a “botton” side) as shown in FIG. 4B. The plates can also be used to hold transition board in place.

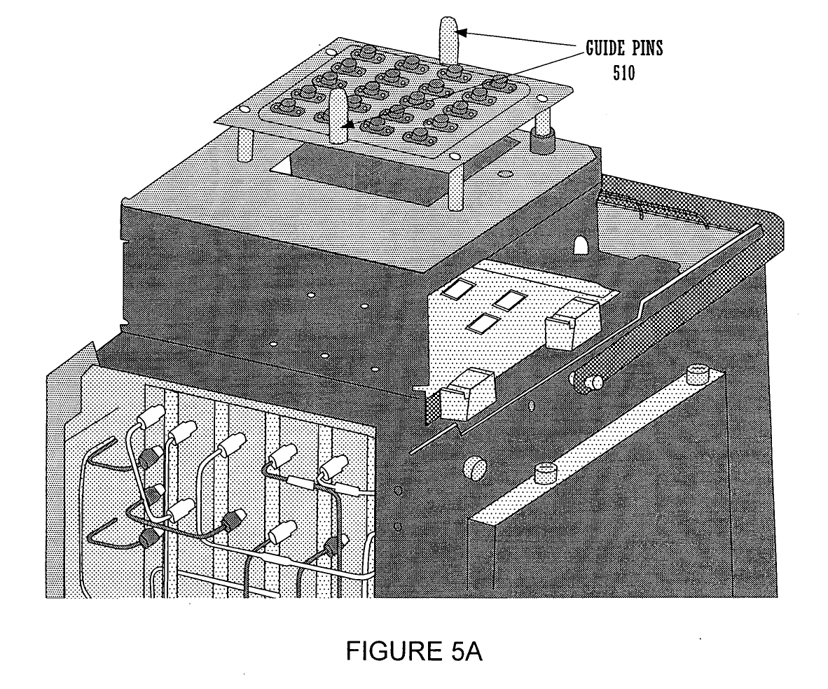

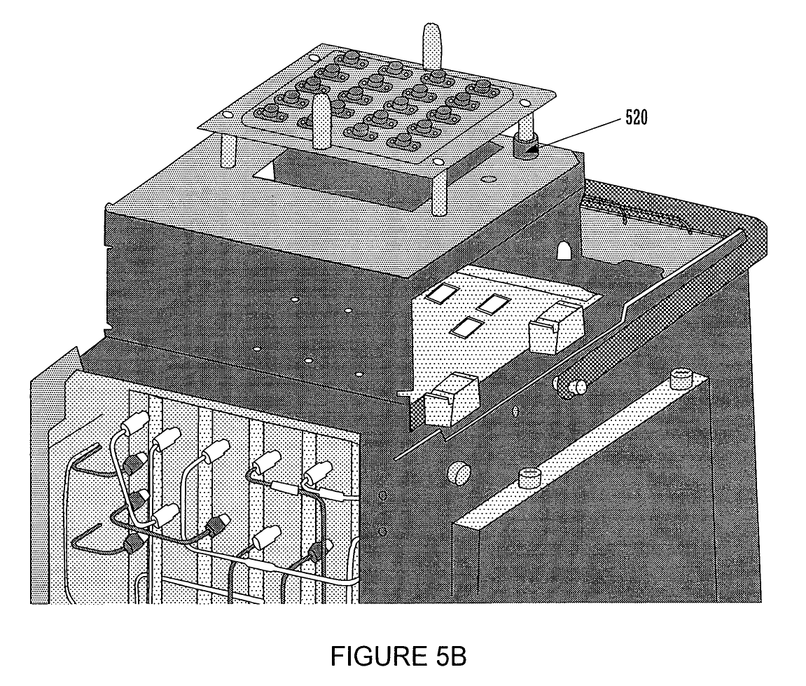

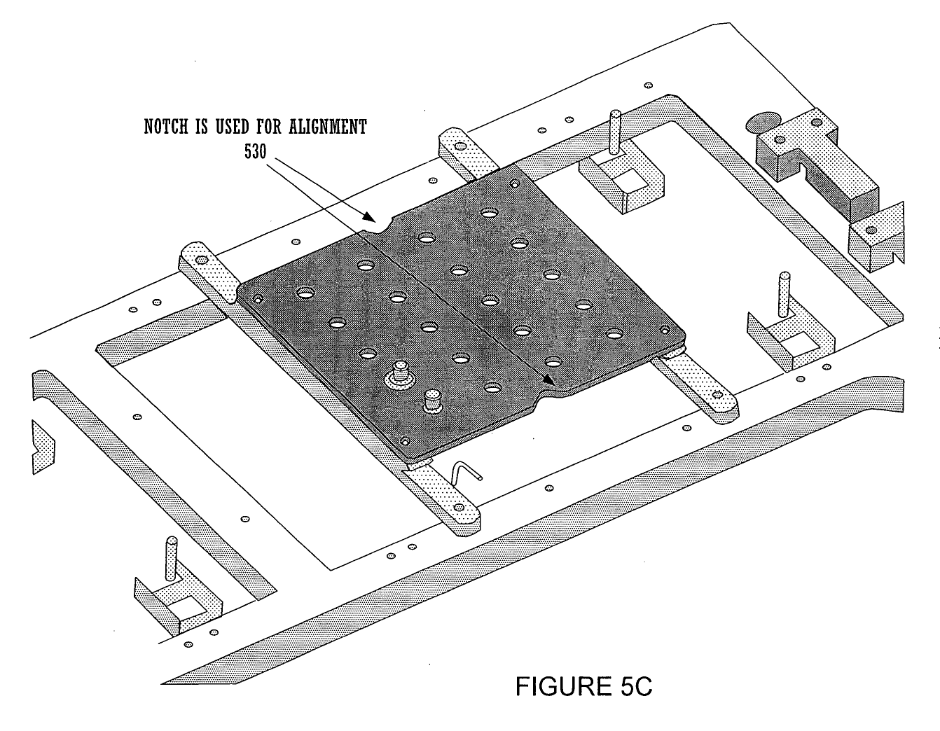

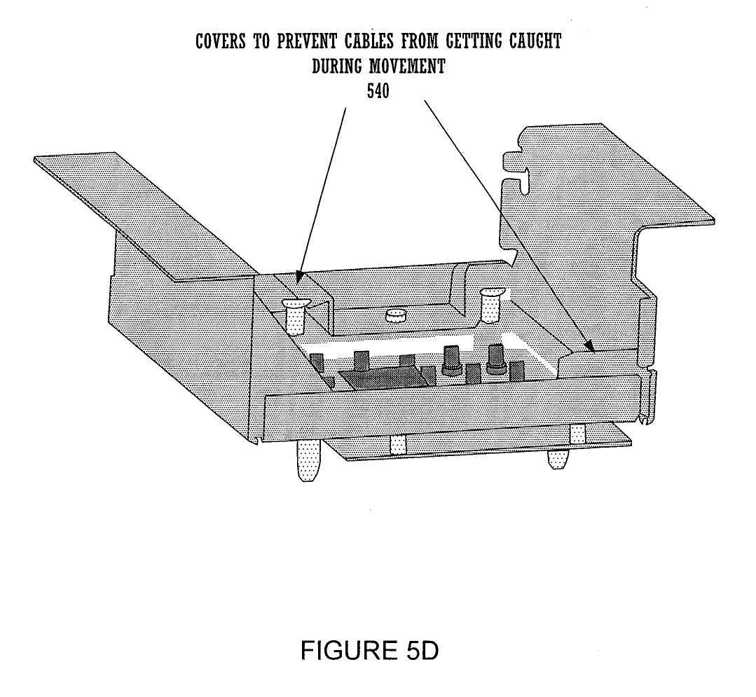

FIGS. 5A and 5B are block diagrams of an OSP bracket 500 in accordance with one embodiment of the present invention. FIG. 5A shows the OSP bracket 400 in an extended position sitting on an RF module. FIG. 5B shows the OSP bracket 400 in a compressed position. In one exemplary implementation, an interface includes plane adjusting components for facilitating plane conversion into a single plane. In one exemplary implementation, a bracket includes adjustable mounting components. For example, an adjustment mounting component can include an adjustable mounting support. The adjustment mounting component can also include a spring 520. In FIG. 5B only one spring is shown, four spring can be used. The adjustment mounting component can also facilitate force adjustment. For example, a spring can provide a “counter” force for facilitating coupling insertion. In one embodiment the force is approximately 60 pounds. It is appreciated that a wide variety of forces can be utilized to accommodate a variety of applications.

An interface can also include alignment features for facilitating alignment of the plurality of buckets and the DUT board to the interface. For example, FIG. 5A shows alignment or guide pins 510 on a bracket. FIG. 5C is a block diagram of an exemplary portion of a load board in accordance with one embodiment of the present invention. FIG. 5C includes a mating bracket with a notch 530 used for alignment sitting on a load-board. In one exemplary implementation, the alignment pin shown in FIG. 5A aligns with the alignment notch shown in FIG. 5C.

FIG. 5D is a block diagram of the bottom view of an exemplary bracket in accordance with one embodiment of the present invention. The exemplary bracket is shown in the compressed configuration. In one exemplary implementation, the bracket includes covers 540 to prevent cables from getting caught during movement.

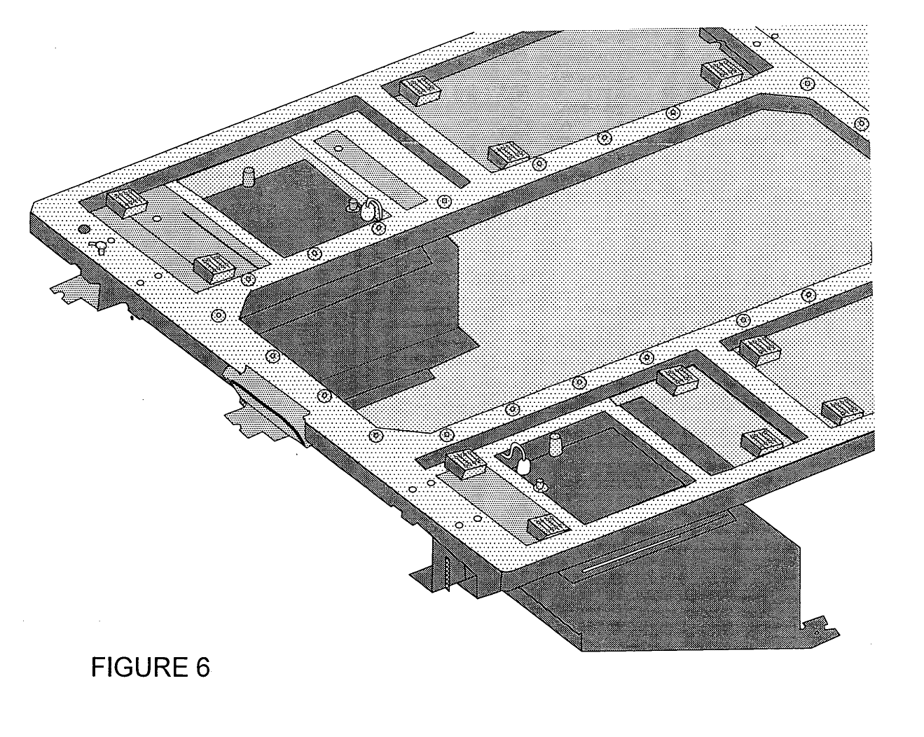

FIG. 6 is diagram of a load board sitting on two RF OSP brackets in accordance with one embodiment of the present invention. The door is hidden.

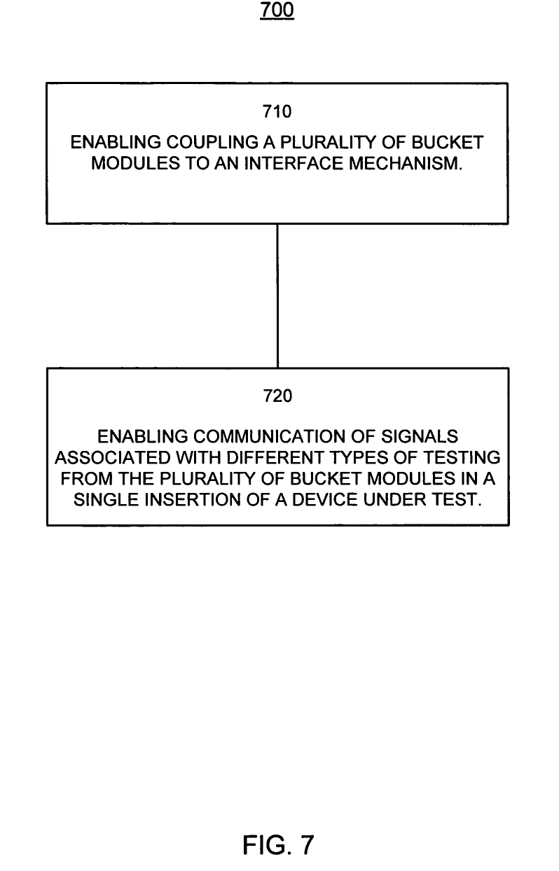

FIG. 7 is a flow chart of a test interface method 700 in accordance with one embodiment of the present invention. In one embodiment, test interface method 700 facilitates coupling test instruments to a device under test via a variety of different connection types. Test interface method 700 can facilitate performance of a variety of different types of testing in a single insertion of a DUT.

In block 710, coupling of a plurality of bucket modules to an interface mechanism is enabled. In one embodiment, the coupling includes applying enough force to secure electrical connections between the plurality of buckets and the interface mechanism. The plurality of bucket modules can include different types of test instruments. The resulting coupling or docking of the interface components can be configured to be in substantially the same plane at a substantially same depth. A bucket can include VHDM connectors, zero insertion force connectors (ZIF), pogo pins, hard co-axial connections, converted SMA connections, OSP compliant connections, etc. There can also be a variety of different connection configurations. In one embodiment, a multi-Amp channel (e.g., 5 Amps) can have a plurality of division (e.g., 5-one amp divisions). The connections can also include a high and low side I/O for both force and sense per each channel and also a high and low I/O guard per each channel. For example, if a device takes 5 divisions of power per channel and there are 60 channels there can be 300 input/output connections.

In block 720, communication of signals associated with different types of testing is enabled from the plurality of bucket modules in a single insertion of a device under test. In one embodiment the coupling includes docking different types of connectors to a portion of the interface for coupling with a device under test in a single insertion.

In one embodiment, coupling of components in method 700 is performed with pneumatic assistance in coupling the components together. The pneumatic assistance can enable an independent coupling of multiple testing buckets to an interface door body and independent coupling of a DUT board to the interface door body. In one exemplary, turning a pneumatic trigger device (e.g., switch) in one direction causes the interface door body to be pulled “down” into contact with connections on the buckets and exerts sufficient and even force for coupling the connections of the buckets to interface mechanisms of the bottom of the door body. Turning a pneumatic trigger device (e.g., switch) in another direction causes the interface door body to pull “down” a DUT board so that connection s on the DUT board couple to connections on the door body and exerts sufficient and even force for coupling the connections together.

Thus, the present invention facilitates efficient automated testing of devices. Interfacing systems and methods of the present invention also facilitate flexible reconfiguration of the “underlying test head” with operator simplicity by permitting efficient inter-connection of different types of testing buckets to a device under test.

The foregoing descriptions of specific embodiments of the present invention have been presented for purposes of illustration and description. They are not intended to be exhaustive or to limit the invention to the precise forms disclosed, and obviously many modifications and variations are possible in light of the above teaching. The embodiments were chosen and described in order to best explain the principles of the invention and its practical application, to thereby enable others skilled in the art to best utilize the invention and various embodiments with various modifications as are suited to the particular use contemplated. It is intended that the scope of the invention be defined by the Claims appended hereto and their equivalents.

What is claimed is:

1. A testing system comprising:
a plurality of bucket modules having similar external connection form factors for a variety of instruments; and
an interface for transitioning connections from said plurality of bucket modules to a device under test

2. A testing system of claim 1 wherein said plurality of bucket modules include a first bucket for performing a first type of test and a second bucket for performing a second type of test.

3. A testing system of claim 2 wherein said first bucket is a radio frequency (RF) test bucket for testing radio frequency features of a device under test and said second bucket is a non radio frequency (non-RF) bucket for testing non radio frequency features of a device under test.

4. A testing system of claim 2 wherein said interface couples instruments in said plurality of buckets to a device under test in a single insertion.

5. A testing system of claim 2 wherein said second bucket is a digital bucket for testing digital features of a device under test.

6. A testing system of claim 2 wherein said second bucket is a linear bucket for testing linear features of a device under test.

7. A testing system of claim 1 wherein said interface includes an interface door that when opened permits access to said plurality of bucket modules.

8. A testing system of claim 1 wherein said interface includes transition mechanisms for facilitating coupling of said plurality of buckets to a device under test board in substantially a same plane.

9. A testing system of claim 1 wherein said interface includes alignment features for facilitating alignment of said plurality of buckets and said DUT board to said interface.

10. A testing system of claim 1 wherein said interface facilitates tighter configuration of connectors to in a device under test board.

11. A test system interface method comprising:
enabling coupling of a plurality of bucket modules to an interface mechanism; and
enabling communication of signals associated with different types of testing from said plurality of bucket modules in a single insertion of a device under test.

12 A test system interface method of claim 11 wherein said coupling includes applying enough force to secure electrical connections between said plurality of buckets and said device under test via said interface mechanism.

13. A test system interface method of claim 11 wherein said coupling includes docking different types of connectors to substantially the same depth.

14. A test system interface method of claim 11 wherein said plurality of bucket modules include different types of test instruments.

15. A test system interface comprising:
a first side for interfacing with a plurality of bucket modules; and
a second side for interfacing with a device under test.

16. A test system interface of claim 15 wherein said first side includes radio frequency (RF) means and non-radio frequency(non-RF) coupling means for coupling radio frequency signals to said interface.

17. A test system interface of claim 15 wherein said second side includes coupling means for coupling RF and non-RF signals to a device under test.

18. A test system interface of claim 15 wherein connectors on said second side are substantially co-resident in the same plane.

19. A test system interface of claim 15 wherein said second side connectors are tighter together.
